(19) United States
(12) Patent Application Publication
(10) Pub. No.: US 2023/0147436 A1
(43) Pub. Date: May 11, 2023

(54) METHOD FOR MANUFACTURING METAL SENSING ELECTRODE STRUCTURE, TOUCH DISPLAY DEVICE AND MOBILE TERMINAL

(71) Applicant: Micron Optoelectronics Co., Ltd., Shenzhen (CN)

(72) Inventors: Wei SU, Shenzhen (CN); Zonghe YE, Shenzhen (CN)

(73) Assignee: Micron Optoelectronics Co., Ltd., Shenzhen (CN)

(21) Appl. No.: 17/979,979

(22) Filed: Nov. 3, 2022

(30) Foreign Application Priority Data
Nov. 5, 2021 (CN) 202111306692.9

(51) Int. Cl. G06F 3/044; G03F 7/00; G03F 7/16; G03F 7/038

(52) U.S. Cl. CPC G06F 3/044; G03F 7/0007; G03F 7/168; G03F 7/038; G06F 2203/04103

(57) ABSTRACT

Disclosed are a method for manufacturing a metal sensing electrode structure, a touch display device and a mobile terminal. The method for manufacturing a metal sensing electrode structure for a capacitive touch screen includes: coating a protective material on a first surface of a first metal foil layer to obtain a first coating layer, wherein a thickness of the first metal foil layer is greater than that of the first coating layer; connecting a surface of the first coating layer opposite to the first metal foil layer with a first optical adhesive layer; and performing a photolithography process on a second surface of the first metal foil layer to obtain a first metal sensing electrode structure.

### CROSS-REFERENCE TO RELATED APPLICATIONS

This application claims priority to Chinese Patent Application No. 202111306692.9, filed on Nov. 5, 2021, the entire contents of which are incorporated herein by reference.

### TECHNICAL FIELD

The present disclosure relates to the technical field of optical films, and in particular, to a method for manufacturing a metal sensing electrode structure, a touch display device and a mobile terminal.

### BACKGROUND

With the development of touch technology, the traditional resistive touch screen is gradually replaced by the thinner capacitive touch screen with better touch performance. The metal sensing electrode structure has been widely used in many capacitive touch screens.

At present, the metal sensing electrode structure is mainly made by the following methods.

(1) Yellow light process subtraction technology: the copper layer is plated on a transparent substrate through vacuum plating, then the copper layer on the transparent substrate is patterned through the yellow light process (pasting photoresist—exposuring—developing—etching—stripping) subtraction technology.

(2) Yellow light process addition technology: using the yellow light process, after patterning the precious metal palladium activation layer on the surface of the transparent substrate, a layer of copper film is covered through electroless plating.

However, the above-mentioned metal sensing electrode structure has thin copper layer, thick substrate and low transmittance.

Specifically, on the one hand, due to the limitation of stress at an interface between vacuum plating or electroless plating and palladium activation layer, the maximum thickness of the copper layer in the metal sensing electrode structure can only reach 2 μm, and a corrosion may occur if there exists a slight acid and alkali erosion or water vapor residue. On the other hand, the metal sensing electrode structures in the two technologies are both made on a polyester resin (PET) substrate. Due to the low visible region transmittance of the PET substrate, the composite transmittance is lower after the metal sensing electrode structure being made on the PET transparent substrate.

Thus, it is difficult to obtain a transparent conductive film with high transmittance and low resistance.

### SUMMARY

The present disclosure provides a method for manufacturing a metal sensing electrode structure, which can effectively solve the problems of thin copper layer, thick substrate and low transmittance of the capacitive touch screen prepared by the existing technology, thus the touch screen is thinner.

According to one aspect of the present disclosure, a method for manufacturing a metal sensing electrode structure is provided, which includes:

coating a protective material on a first surface of a first metal foil layer to obtain a first coating layer, a thickness of the first metal foil layer being greater than that of the first coating layer;

connecting a surface of the first coating layer opposite to the first metal foil layer with a first optical adhesive layer; and

performing a photolithography process on a second surface of the first metal foil layer to obtain a first metal sensing electrode structure.

In an embodiment, a material of the first coating layer includes but is not limited to acrylic resin, ethylene-acetic acid copolymer, and polyvinyl butyral.

In an embodiment, the operation of coating the protective material on the first surface of the first metal foil layer includes:

wetting a coating material with a solvent and a dispersant and stirring the coating material to form a coating paste;

applying the coating paste on the first surface of the first metal foil layer to a preset thickness to form a middleware; and

drying the middleware to dehydrate the coating paste, and acquiring the first coating layer.

In an embodiment, after the operation of performing the photolithography process on the second surface of the first metal foil layer to obtain the first metal sensing electrode structure, the method further includes:

forming a first blackening layer on other surfaces of the first metal sensing electrode structure except the surface in touch with the first coating layer; and

forming a second coating layer on other surfaces of the first blackening layer except the surface in touch with the first metal sensing electrode structure, a material of the second coating layer including but is not limited to acrylic resin, ethylene-acetic acid copolymer, and polyvinyl butyral.

In an embodiment, the operation of forming the second coating layer on other surfaces of the first blackening layer except the surface in touch with the first metal sensing electrode structure includes:

wetting a coating material with a solvent and a dispersant and stirring the coating material to form a coating paste;

applying the coating paste to the other surfaces of the first blackening layer except the surface in touch with the first metal sensing electrode structure to a preset thickness to form a middleware; and

drying the middleware to dehydrate the coating paste, and acquiring the second coating layer.

In an embodiment, while applying the coating paste to the other surfaces of the first blackening layer except the surface in touch with the first metal sensing electrode structure, applying the coating paste to the surface of the first coating layer that is not in contact with the first metal sensing electrode structure.

In an embodiment, the method further includes:

coating the protective material on a first surface of the second first metal foil layer to obtain a third coating layer;

connecting a surface of the third coating layer opposite to the second metal foil layer with a second optical adhesive layer;

performing a photolithography process on a second surface of the second metal foil layer to obtain a second metal sensing electrode structure;

attaching the first metal sensing electrode structure with the second metal sensing electrode structure to obtain the metal sensing electrode structure for the capacitive touch screen.

According to another aspect of the present disclosure, a touch display device is provided, including: a glass cover, a third optical adhesive layer, a metal sensing electrode structure manufactured by the method, and a display panel module arranged in sequence.

According to yet another aspect of the present disclosure, a mobile terminal is provided, including the touch display device.

The present disclosure provides a method for manufacturing a metal sensing electrode structure, which can effectively increase the thickness of the copper layer and reduce the surface resistance of the touch screen. Compared with the method for manufacturing the metal sensing electrode structure in the related art, the method in the present disclosure does not depend on any polymer substrate, and the overall thickness of the prepared metal sensing electrode structure is significantly thinner, which improves the total transmittance of the film and make the touch screen thinner.

### BRIEF DESCRIPTION OF THE DRAWINGS

The accompanying drawings described herein are used to provide a further understanding of the present disclosure and constitute a part of the present disclosure. The schematic embodiments of the present disclosure and their descriptions are used to explain the present disclosure and do not constitute an improper limitation of the present disclosure.

FIG. 1 is a flowchart of a method for manufacturing a metal sensing electrode structure for a capacitive touch screen according to an embodiment of the present disclosure.

FIG. 2 is a flowchart of a method for coating the protective material on the first surface of the first metal foil layer according to an embodiment of the present disclosure.

FIG. 3 is a schematic diagram of applying the coating paste on the first surface of the first metal foil layer according to an embodiment of the present disclosure.

FIG. 4 is a flowchart of a method for forming the second coating layer on other surfaces of the first blackening layer except the surface in touch with the first metal sensing electrode structure according to an embodiment of the present disclosure.

FIG. 5 is a flowchart of a method for manufacturing a metal sensing electrode structure for a capacitive touch screen according to an embodiment of the present disclosure.

FIG. 6 is a flowchart of a method for manufacturing a metal sensing electrode structure according to an embodiment of the present disclosure.

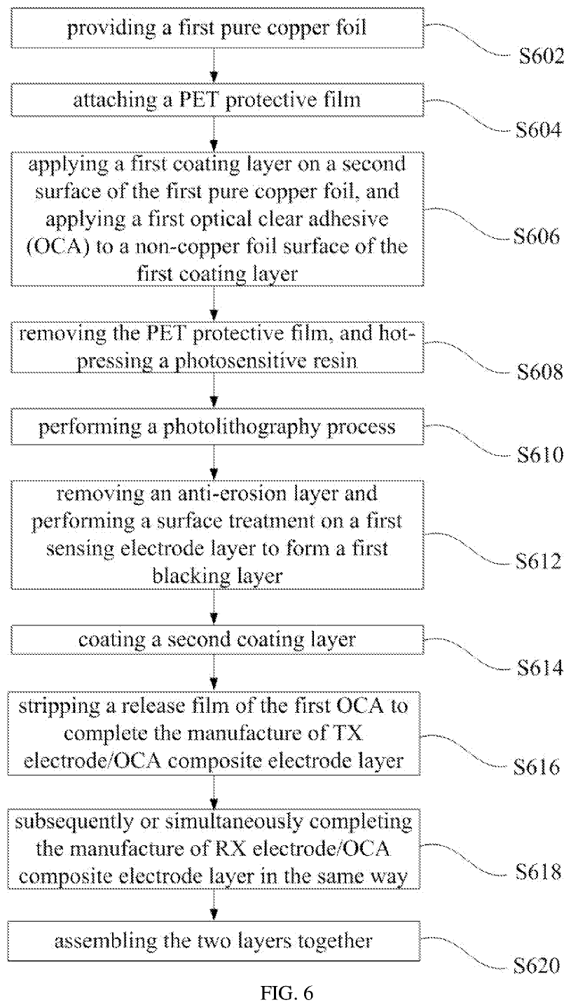

### DETAILED DESCRIPTION OF THE EMBODIMENTS

It should be noted that the embodiments in the present disclosure and the features of the embodiments may be combined with each other in the case of no conflict. The present application will be described in detail below with reference to the accompanying drawings and in conjunction with the embodiments.

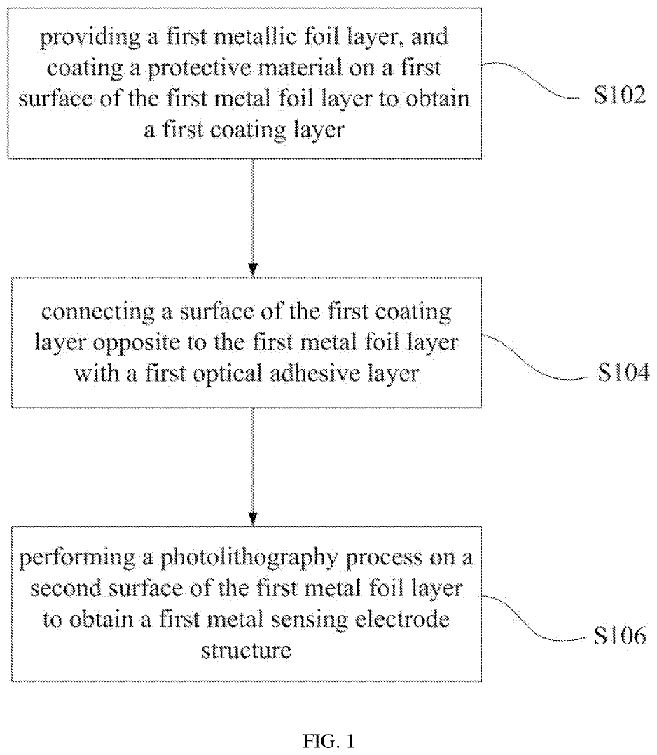

An embodiment of the present disclosure provides a method for manufacturing a metal sensing electrode structure for capacitive touch screen. FIG. 1 is a flowchart of a method for manufacturing a metal sensing electrode structure for a capacitive touch screen according to an embodiment of the present disclosure. Referring to FIG. 1, the method includes:

S102: providing a first metallic foil layer, and coating a protective material on a first surface of the first metal foil layer to obtain a first coating layer. The first metallic foil layer can be a pure copper foil.

S104: connecting a surface of the first coating layer opposite to the first metal foil layer with a first optical adhesive layer.

S106: performing a photolithography process on a second surface of the first metal foil layer to obtain a first metal sensing electrode structure. In this operation, after the procedures of coating a light resistance or a dry film, light-exposure, projection, etching, removing the light resistance or the dry film, depicting, through the procedure of light-exposure and developing, a geometric figure structure on the photoresist layer, then transferring, through the etching technology, a graphic on a photomask to the substrate, eventually patterning the first metal foil layer, and obtaining the first metal sensing electrode structure.

It should be noted that the first coating material includes but is not limited to acrylic resin, ethylene-acetic acid copolymer, and polyvinyl butyral. Acrylic resin coating material is taken as an example, which is a thermoplastic or thermosetting resin coating or acrylic radiation coating made of acrylic resin obtained by copolymerizing (meth)acrylate and styrene as the main body with other acrylates. The acrylic resin coating material is coated on the first metal foil layer through coating technology, which can protect the bottom of the metal foil from being eroded and prevent the optical adhesive layer from being affected by the liquid chemicals during the photolithography process, thus ensuring the work stability.

It is worth noting that the thickness of the first metal foil layer is greater than that of the first coating layer. In the existing Glass-Film-Film (GFF) structure, if the PET substrate is too thin, the metal coating is prone to curling, while if the substrate is too thick, the future trend of lightness and thinness will be lost. Therefore, there is an irreconcilable contradiction between overall lightness and thinness and eliminating the influence of curling. In an embodiment of the present disclosure, the thickness of first metal foil layer is greater than that of the first coating layer, even in the case of no substrate bearing, the first metal foil layer is thick enough to eliminate the curl caused by a tension of the coating layer, so that the adverse effects that the upper and lower materials may not be flattened during compounding and wrinkle after compounding may be eliminated while improving the total transmittance of the thin film and achieving the lightness and thinness of the touch screen.

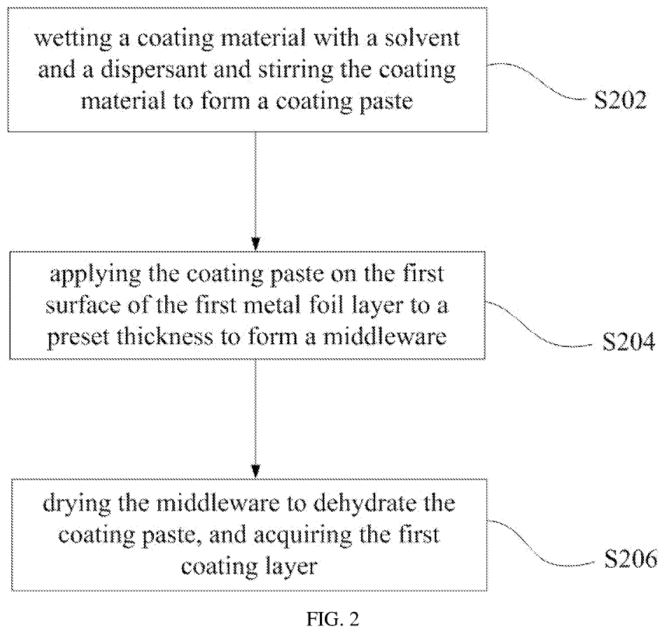

Referring to FIG. 2, the operation S102 of coating the protective material on the first surface of the first metal foil layer includes:

S202: wetting a coating material with a solvent and a dispersant and stirring the coating material to form a coating paste.

S204: applying the coating paste on the first surface of the first metal foil layer to a preset thickness to form a middleware.

S206: drying the middleware to dehydrate the coating paste, and acquiring the first coating layer.

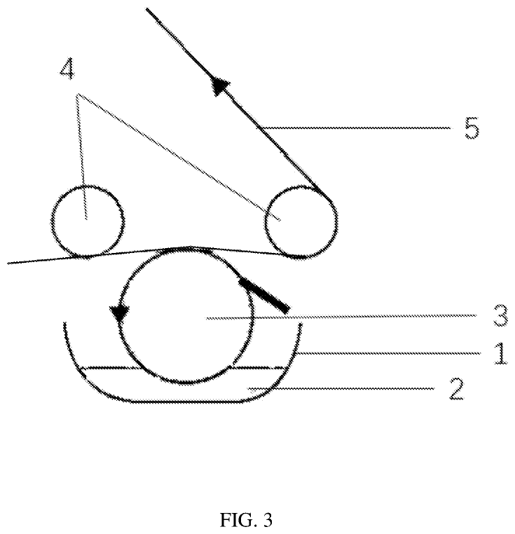

FIG. 3 is a schematic diagram of applying the coating paste on the first surface of the first metal foil layer. Referring to FIG. 3, the parts in the figure are: a liquid supply tank 1, a coating paste 2, an anilox wheel 3, a guide wheel 4, and a metal foil layer 5. Before coating the metal foil layer 5, in order to provide support and protect the copper foil during the coating process, a polyethylene terephthalate (PET) protective film can be attached to a non-coated surface of the metal foil layer 5. During the coating process, a rotation direction of the anilox wheel 3 is opposite to a feeding direction of the metal foil layer 5. The coating paste 2 is applied on the surface of the metal foil layer 5 by cutting to ensure the uniformity of the coating, so as to avoid an occasion where part of the coating paste is coated on the material film, and part of coating paste remains on the anilox wheel 3 during the coating process. During the coating process, the ratio of the feeding speed of the metal foil layer 5 to the rotation speed of the anilox wheel 3 is the main factor for controlling the coating amount. When the metal foil layer 5 gets a feeding speed and the anilox wheel 3 is static, there is no coating amount at this moment. As the rotation speed of the anilox wheel 3 increases, the coating amount will increase, and an overflow may occur. When the rotation speed of the anilox wheel 3 further increases, the coating amount will decrease.

According to a test determination of the present disclosure, the ratio of the coating amount and the speed may form a hump curve. When the speed ratio of the surface line speed of the anilox wheel 3 to the line speed of the metal foil layer 5 is 60%, the coating starts. When the speed ratio is between 100% to 130%, the coating is uniform and regular. When the speed ratio is between 130% to 200%, the coating amount increases. When the speed ratio is above 200%, the coating amount decreases, and an instability may occur. Although the coating amount is related to the volume of the anilox wheel 3, there exists a window on the curve that usually when the ratio is between 100% to 130%, the thickness or weight of the coating can be effectively controlled, and a uniform coating surface can be ensured. Through a certain number of the anilox wheels 3 with different line numbers, various amount of the coating can be obtained, and a relatively economical effect can be achieved. In reference to the transmission ratio, adjusting the anilox wheel 3 can basically obtain a relatively continuous amount of the coating. As for the coating with stricter requirements, the curve between the coating amount and the speed ratio can be drawn in combination with a mesh size of the anilox wheel 3 and a rheological property of a glue.

In an embodiment of the present disclosure, after the operation S106 of performing the photolithography process on the second surface of the first metal foil layer to obtain a first metal sensing electrode structure, the method further includes:

S108: forming a first blackening layer on other surfaces of the first metal sensing electrode structure except the surface in touch with the first coating layer. The first blackening layer can be made by a generation method or a replacement method. The manufacturing material of the first blackening layer can be copper oxide, copper selenide, and copper sulfide.

S110: forming a second coating layer on other surfaces of the first blackening layer except the surface in touch with the first metal sensing electrode structure.

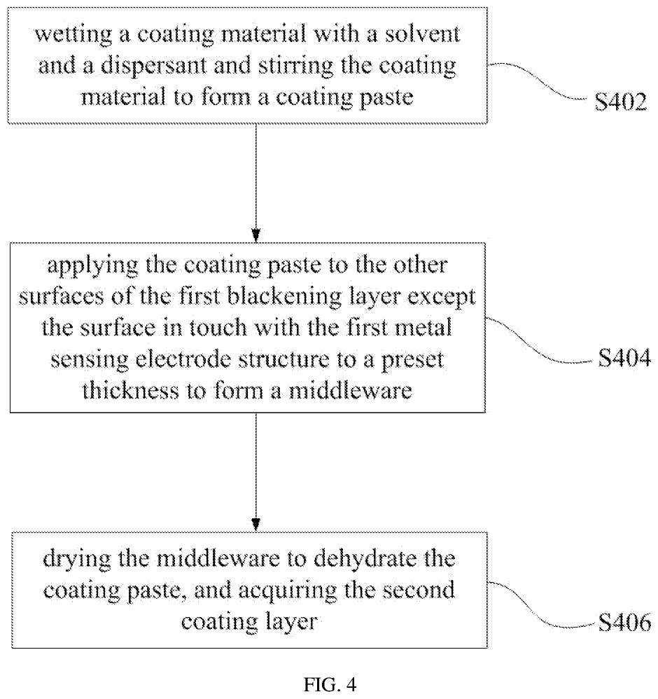

Referring to FIG. 4, the operation S110 of forming a second coating layer on other surfaces of the first blackening layer except the surface in touch with the first metal sensing electrode structure includes:

S402: wetting a coating material with a solvent and a dispersant and stirring the coating material to form a coating paste.

S404: applying the coating paste to the other surfaces of the first blackening layer except the surface in touch with the first metal sensing electrode structure to a preset thickness to form a middleware.

S406: drying the middleware to dehydrate the coating paste, and acquiring the second coating layer.

In the operation S404, while applying the coating paste to the other surfaces of the first blackening layer except the surface in touch with the first metal sensing electrode structure, the coating paste is applied to the surfaces of the first coating layer which are not in touch with first metal sensing electrode structure.

The method for manufacturing a second coating layer can also refer to that of the first coating layer. During the coating process, a rotation speed of the anilox wheel is opposite to a feeding speed of the first metal sensing electrode structure forming the first blacking layer. While applying the coating paste to the other surfaces of the first blackening layer except the surface in touch with the first metal sensing electrode structure through cutting, the coating paste is applied to the surfaces of the first coating layer which are not in touch with first metal sensing electrode structure. During the coating process, the ratio of the feeding speed and the speed of the anilox wheel remains a main factor for controlling the coating amount.

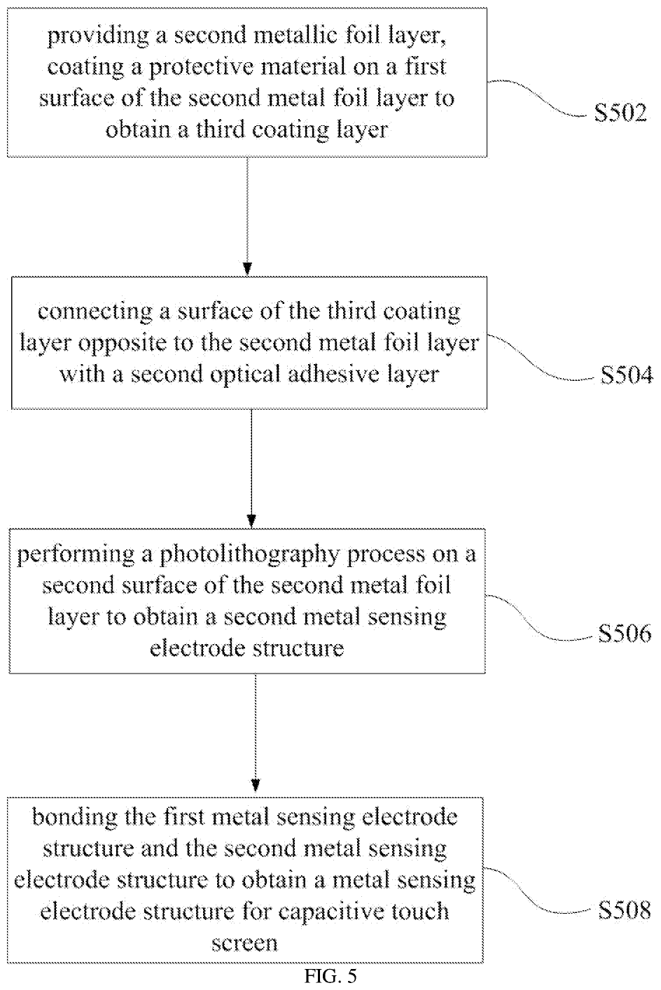

FIG. 5 provides a method for manufacturing a metal sensing electrode structure for a capacitive touch screen. Referring to FIG. 5, obtaining the metal sensing electrode structure for a capacitive touch screen at least includes:

S502: providing a second metallic foil layer, coating a protective material on a first surface of the second metal foil layer to obtain a third coating layer. The second metallic foil layer can be a pure copper foil.

S504: connecting a surface of the third coating layer opposite to the second metal foil layer with a second optical adhesive layer.

S506: performing a photolithography process on a second surface of the second metal foil layer to obtain a second metal sensing electrode structure. In this operation, after the procedures of coating a light resistance or a dry film, light-exposure, projection, etching, removing the light resistance or the dry film, depicting, through the procedure of light-exposure and developing, a geometric figure structure on the photoresist layer, then transferring, through the etching technology, a graphic on a photomask to the substrate, eventually patterning the second metal foil layer, and obtaining the second metal sensing electrode structure.

S508: Bonding the first metal sensing electrode structure and the second metal sensing electrode structure to obtain a metal sensing electrode structure for capacitive touch screen.

It should be noted that the third coating material includes but is not limited to acrylic resin, ethylene-acetic acid copolymer, and polyvinyl butyral. Acrylic resin coating material is taken as an example, which is a thermoplastic or thermosetting resin coating or acrylic radiation coating made of acrylic resin obtained by copolymerizing (meth)acrylate and styrene as the main body with other acrylates. The acrylic resin coating material is coated on the first metal foil layer through coating technology, which can protect the bottom of the metal foil from being eroded and prevent the optical adhesive layer from being affected by the liquid chemicals during the photolithography process, thus ensuring the work stability.

The method for manufacturing a third coating layer can also refer to that of the first coating layer. During the coating process, a rotation direction of the anilox wheel 3 is opposite to a feeding direction of the metal foil layer 5. The coating paste 2 is applied on the surface of the metal foil layer 5 by cutting. During the process of a micro anilox coating, the ratio of the feeding speed of the metal foil layer to the rotation speed of the anilox wheel is the main factor for controlling the coating amount. When the metal foil layer gets a feeding speed and the anilox wheel is static, there is no coating amount at this moment. As the speed of the anilox wheel 3 increases, the coating amount will increase, and an overflow may occur. When the rotation speed of the anilox wheel 3 further increases, the coating amount will decrease. According to a test determination of the present disclosure, the ratio of the coating amount and the speed may form a hump curve. When the speed ratio is between 100% to 130%, the thickness or weight of the coating can be effectively controlled, and a uniform coating surface can be ensured.

It should be noted that the method for manufacturing the second metal sensing electrode structure is the same as that of the first metal sensing electrode structure. The second metal sensing electrode structure can be manufactured at the same time as manufacturing the first metal sensing electrode structure, and can also be manufactured after manufacturing the first metal sensing electrode structure. The manufacturing sequence of the first metal sensing electrode structure and the second metal sensing electrode structure is not restricted in the present disclosure.

An embodiment of the present disclosure also provides a touch display device. The capacitive touch screen includes a glass cover plate, a third optical adhesive layer, a metal sensing electrode structure manufactured by the method of the present disclosure, and a display panel module, which are arranged in sequence. The foregoing specification has clearly disclosed that the metal sensing electrode structure of the present disclosure includes at least a first metal sensing electrode structure, a first coating layer, a first optical adhesive layer, a second metal sensing electrode structure, a third coating layer and a second optical adhesive layer, which are sequentially arranged. In the touch display device, the glass cover plate is connected to a first surface of the third optical adhesive layer, a second surface of the third optical adhesive layer is connected to the metal sensing electrode structure, and the second optical adhesive layer in the metal sensing electrode structure is connected to the display panel module.

Depending on the type of touch display device, the display panel module can be a liquid crystal display (LCD) display panel module, an organic light-emitting diode (OLED) display panel module, a Mini light-emitting diode (Mini LED) display panel module, a Micro light-emitting diode (Micro LED) display panel module or an active-matrix organic light-emitting diode (AMOLED) display panel module.

Further, the present disclosure does not restrict that the touch display device must be an independent device, which can also be integrated into an electronic device, such that the electronic device has both touch and display functions. The electronic device can be a smart phone, a tablet computer, a laptop, an All-in-One computer, a smart watch, a door machine, a nano blackboard, an intelligent all-in-one machine or a conference machine.

The embodiment of the present disclosure also provides a method for manufacturing a metal sensing electrode structure, including the following operations S602 to S620:

S602: providing a first pure copper foil, which can be a rolled copper foil or an electrolytic copper foil with a thickness between 0.5 and 100 um.

S604: attaching a PET protective film, which plays a supporting role, to a first surface of the first pure copper foil.

S606: applying a first coating layer on a second surface of the first pure copper foil, and applying a first optical clear adhesive (OCA, the release film is provided with the optical adhesive), to a non-copper foil surface of the first coating layer. The material of the first coating layer includes but is not limited to acrylic resin, ethylene-acetic acid copolymer, and polyvinyl butyral.

S608: removing the PET protective film, and hot-pressing a photosensitive resin on the surface of the first pure copper foil.

S610: performing a photolithography process on the product by the preceding operations to obtain the first metal sensing electrode structure.

S612: removing an anti-erosion layer and an oxidation layer of the pure copper foil through an acid solution, performing a surface treatment on a first sensing electrode layer to form a first blacking layer. The first blacking layer can be made through a generating method or a displacement method, the thickness of which is between 40 nm to 500 nm.

S614: coating a second coating layer on the first blackening layer.

S616: stripping a release film of the first OCA to complete the manufacture of TX electrode/OCA composite electrode layer.

S618: subsequently or simultaneously completing the manufacture of RX electrode/OCA composite electrode layer in the same way.

S620: assembling the two layers together.

To sum up, according to the embodiments of the present disclosure, a method for manufacturing a metal sensing electrode structure is provided, which can effectively increase the thickness of the copper layer and reduce the surface resistance of the touch screen. Compared with the method for manufacturing the metal sensing electrode structure in the related art, the method in the present disclosure does not depend on any polymer substrate, and the overall thickness of the prepared metal sensing electrode structure is significantly thinner, which improves the total transmittance of the film and make the touch screen thinner.

The above description is only an embodiment of the present disclosure, and is not intended to limit the present disclosure. For those skilled in the art, the present disclosure may have various modifications and changes. Any modification, equivalent replacement, improvement made within the spirit and principle of the present disclosure shall be included within the protection scope of the present disclosure.

What is claimed is:

1. A method for manufacturing a metal sensing electrode structure for a capacitive touch screen, comprising:
coating a protective material on a first surface of a first metal foil layer to obtain a first coating layer, wherein a thickness of the first metal foil layer is greater than that of the first coating layer;
connecting a surface of the first coating layer opposite to the first metal foil layer with a first optical adhesive layer; and
performing a photolithography process on a second surface of the first metal foil layer to obtain a first metal sensing electrode structure.

2. The method of claim 1, wherein a material of the first coating layer comprises acrylic resin, ethylene-acetic acid copolymer, and polyvinyl butyral.

3. The method of claim 1, wherein the operation of coating the protective material on the first surface of the first metal foil layer comprises:
wetting a coating material with a solvent and a dispersant and stirring the coating material to form a coating paste;
applying the coating paste on the first surface of the first metal foil layer to a preset thickness to form a middleware; and
drying the middleware to dehydrate the coating paste, and acquiring the first coating layer.

4. The method of claim 1, wherein after the operation of performing the photolithography process on the second surface of the first metal foil layer to obtain the first metal sensing electrode structure, the method further comprises:
forming a first blackening layer on other surfaces of the first metal sensing electrode structure except the surface in touch with the first coating layer; and
forming a second coating layer on other surfaces of the first blackening layer except the surface in touch with the first metal sensing electrode structure, wherein a material of the second coating layer comprises acrylic resin, ethylene-acetic acid copolymer, and polyvinyl butyral.

5. The method of claim 4, wherein the operation of forming the second coating layer on other surfaces of the first blackening layer except the surface in touch with the first metal sensing electrode structure comprises:
wetting a coating material with a solvent and a dispersant and stirring the coating material to form a coating paste;
applying the coating paste to the other surfaces of the first blackening layer except the surface in touch with the first metal sensing electrode structure to a preset thickness to form a middleware; and
drying the middleware to dehydrate the coating paste, and acquiring the second coating layer.

6. The method of claim 5, further comprising applying the coating paste to the surface of the first coating layer that is not in contact with the first metal sensing electrode structure while applying the coating paste to the other surfaces of the first blackening layer except the surface in touch with the first metal sensing electrode structure.

7. The method of claim 1, further comprising:
coating the protective material on a first surface of the second first metal foil layer to obtain a third coating layer;
connecting a surface of the third coating layer opposite to the second metal foil layer with a second optical adhesive layer;
performing a photolithography process on a second surface of the second metal foil layer to obtain a second metal sensing electrode structure; and
attaching the first metal sensing electrode structure with the second metal sensing electrode structure to obtain the metal sensing electrode structure for the capacitive touch screen.

8. A touch display device, comprising: a glass cover, a third optical adhesive layer, a metal sensing electrode structure manufactured by the method of claim 1, and a display panel module arranged in sequence.

9. A mobile terminal comprising the touch display device of claim 8.
